(19) United States
(12) Patent Application Publication
(10) Pub. No.: US 2003/0020531 A1
(43) Pub. Date: Jan. 30, 2003

(54) CMOS buffer with significantly improved ground bounce reduction

(75) Inventor: Rajesh Kaushik, Haryana (IN)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics Ltd., Uttar Pradesh (IN)

(21) Appl. No.: 10/206,135

(22) Filed: Jul. 26, 2002

(30) Foreign Application Priority Data
Jul. 27, 2001 (IN) 804/DEL/2001

(51) Int. Cl. H03K 17/16

(52) U.S. Cl. 327/380

(57) ABSTRACT

A CMOS output buffer uses feedback from a ground node to reduce ground bounce by utilizing a tolerable ground bounce limit, making it less sensitive to operating conditions and processing parameters. An input to the NMOS device of the output buffer is provided by the output of a control element which receives a first input from a pre-driver and a second input (i.e., the feedback) from the ground node.

### FIELD OF THE INVENTION

The present invention relates to the field of integrated circuits, and, more particularly, to a CMOS buffer.

### BACKGROUND OF THE INVENTION

In integrated circuits, output buffers are used for interfacing core logic with external devices. One prominent problem in output buffers is “ground bounce.” More particularly, one basic property of an inductor is that the change of current therethrough produces a voltage across the inductor, which is directly proportional to the rate of change of current through the inductor. This may be represented as:

dV=LdI/dT,

where dV is the voltage generated, L is the inductance, and dI/dT is the rate of change of the current.

Thus, it may be said that the voltage across the inductor bounces. When considered at the ground pin, this is referred to as ground bounce. Ground bounce occurs as a result of parasitic inductance of the integrated circuit and packaging interconnections. Ground bounce occurs when the pull down transistor switches from an off to an on state.

Referring to FIG. 1, when the pull down transistor N116 is turned ON, the potential developed across the capacitor C122 is coupled by the transistor N116 to the inductor L120. As a result, a transient is generated across inductor L120. A sudden increase of current flows from the output terminal 0112 through the pull-down transistor N116 and through the parasitic inductance L120 to ground.

Due to the above noted properties of an inductor, the voltage at the source of the pull down transistor rises. This decreases the gate-source voltage of the pull down transistor. In the case where this rise in source voltage is very large, it can cause ringing, which is reflected in the output of other buffers which are connected to the same ground pin and whose outputs are stable at a low level. The worst case is when all of the buffers, except one whose output is stable at a low level, are connected between the same supply pins and switch from high to low, which may lead to false triggering if the ground bounce is not kept within certain limits. This, in turn, imposes a limit on the number of output buffers that can be connected to a single ground pin, thus increasing the number of ground pins on a chip.

Various techniques have been used to reduce ground bounce. For example, U.S. Pat. No. 5,124,579 discloses the use of a resistive device for delaying the turn-on time of the output transistors to limit the rate of increase of ground current. Yet, this method is limited in its ability to dynamically adjust to changing output conditions. Furthermore, the delays produced are manufacturing process dependent.

Another approach is disclosed in U.S. Pat. No. 5,148,056, in which feedback is taken from the output terminal of the buffer. However, this technique has poor sensitivity to the actual ground bounce, especially when it is produced by the switching of other buffers. Further, U.S. Pat. No. 5,604,453 teaches an approach which relies on the matching of the geometries of various individual devices rather than feedback. As a result, this approach is incapable of dynamically adjusting to changing output conditions. Mismatches arising out of process variations would also influence the effectiveness of this approach.

### SUMMARY OF THE INVENTION

An object of the present invention is to overcome the above drawbacks and to provide a CMOS buffer with reduced ground bounce.

These and other objects, features, and advantages in accordance with the invention are provided by a CMOS buffer with reduced ground bounce which may include feedback means or circuit for sensing the ground bounce voltage at a ground terminal. The feedback circuit may be connected to the input of a controlling means or circuit for dynamically adjusting the rate of increase of the ground current in a manner that reduces the sensed ground bounce voltage to a level below a threshold while maintaining a desired speed of operation.

The feedback circuit may include an amplifier that amplifies the difference between the sensed output ground voltage and an internal reference ground voltage. The controlling circuit may include a slew-rate controlling circuit, for example. In particular, the slew-rate controlling circuit may dynamically adjust the gate voltage of the output NMOS transistor to limit the rate of increase of the current through the ground terminal.

### BRIEF DESCRIPTION OF THE DRAWINGS

The invention will now be described with reference to the accompanying drawings, in which:

FIG. 1 is a schematic diagram of a basic inverter with parasitic package inductances in accordance with the prior art;

FIG. 2 is a schematic diagram of CMOS output buffers in accordance with the present invention;

FIG. 3 is a schematic block diagram of a control element configuration for use with the CMOS output buffers of FIG. 2;

FIG. 4 is a schematic block diagram of an alternate control element configuration for use with the CMOS output buffers of FIG. 2; and

FIG. 5 is a flowchart illustrating operation of a CMOS output buffer in accordance with the present invention.

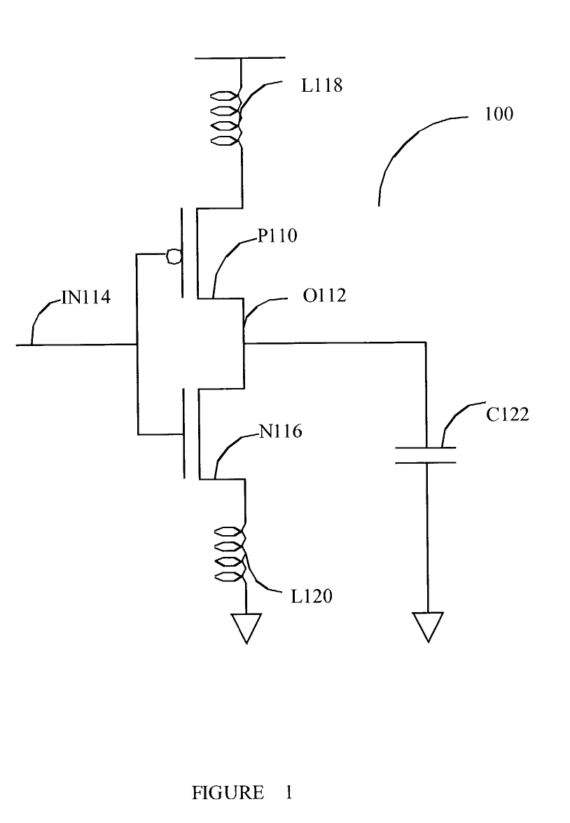

### DETAILED DESCRIPTION OF THE PREFERRED EMBODIMENTS

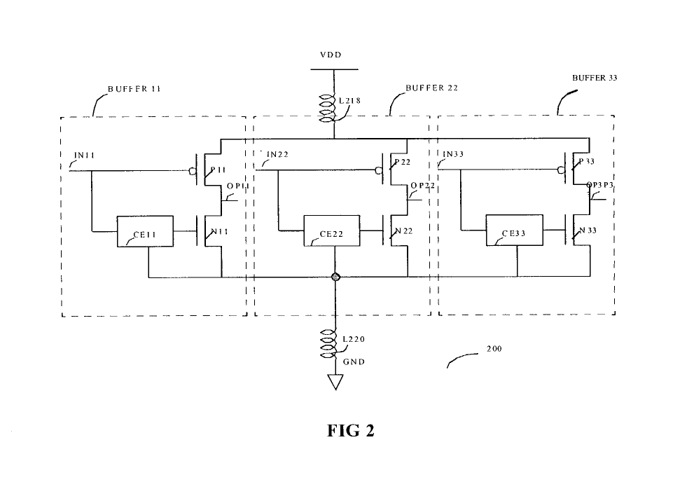

Referring to FIG. 2, three output buffers BUFFER11, BUFFER22, and BUFFER33 in accordance with the invention are connected between common supplies VDD and GND through package inductances on the VDD and GND pins illustratively represented as inductors L218 and L220, respectively. The inputs to the buffers are IN11, IN22, and IN33, respectively, and the outputs are OP11, OP22, and OP33, respectively. Each buffer BUFFER11, BUFFER22, and BUFFER33 has its input connected to its pull-down transistor through a respective control element CE11, CE22, and CE33.

One configuration of a control element is illustrated in FIG. 3. Here, only BUFFER11 is considered for clarity of illustration. Input IN11 is connected to one end of the slew rate control element 305, while it receives its other input 302 from an amplifier 304. The amplifier 304 receives as its input 301 feedback from the inductor L220. The voltage at the input 301 varies dynamically according to ground bounce. This voltage is used to keep the bounce under control and at a selected level.

When the ground bounce at input 301 increases to a specific level, it increases the slew of the output signal on output 303 provided to the pull-down transistor N11. Further, when the ground bounce is not present, the input signal IN11 passes through the control element CE11 without any changes and reaches the gate of pull-down transistor N11.

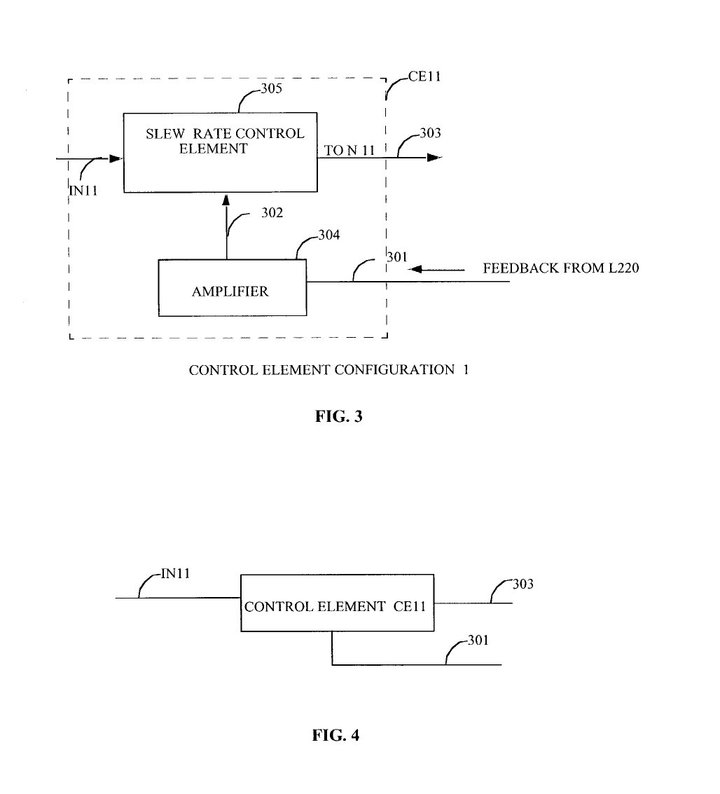

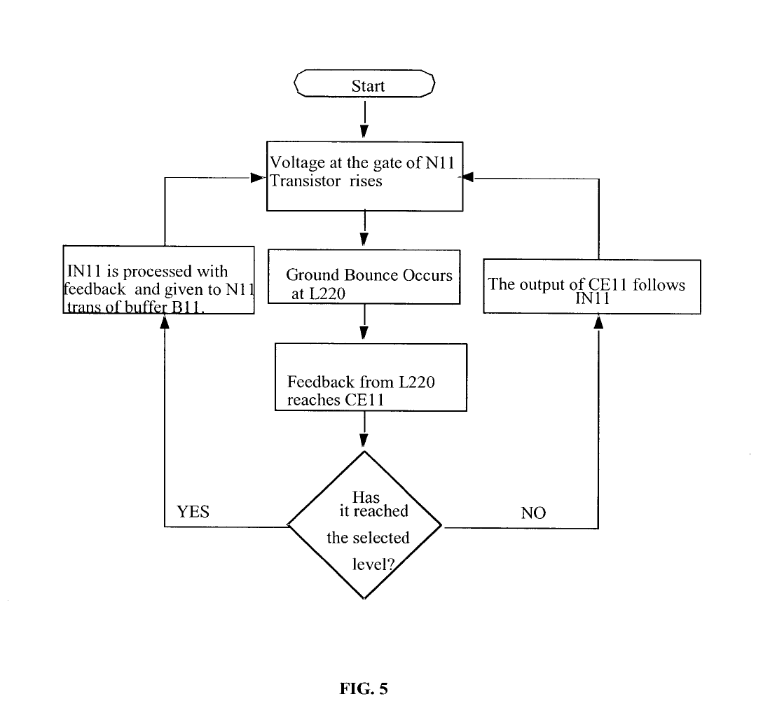

An alternate control element configuration is illustrated in FIG. 4. The output 303 of control element CE11 is processed according to a given formula which depends upon the type of package and technology used.

A steady state condition will now be considered with reference to FIG. 2 where the input signal IN11 of the BUFFER11 is low, the input signal IN22 of the BUFFER22 is high, and the input signal IN33 of the BUFFER33 is also high. The pull-up transistor P11 is ON, P22 is OFF, and P33 is OFF. The pull-down transistor N11 is OFF, N22 is ON, and N33 is ON. The output of control element CE11 is low, as at this moment there is no bounce at the inductor L220. This pulls up the node OP11 high and also charges the load connected thereto. As the pull-down transistors N22 and N33 are ON, OP22 and OP33 are pulled down and stable at a low level.

Now we will consider the case when the input IN11 is switching from a low to high state. During this switching, as the bounce is produced in the inductor L220 it is fed back to the control element CE11. After the feedback has reached a particular selected level, the control element CE11 circuitry controls the output provided to the pull-down transistor N11 by increasing the slew of the signal on the output 303, thus regulating the current therethrough which decreases the ground bounce at L220. Due to this decrease in ground bounce, feedback magnitude also decreases and the input to the gate of the transistor N11 rises faster (i.e., with decreased slew), which again increases ground bounce. This cycle is repeated until the voltage at IN11 reaches its high state.

The above will be further understood with reference to the flow diagram of FIG. 5. The selected level of feedback (which is low as compared to the maximum tolerable ground bounce) at which the control element circuitry becomes active is determined based upon the delay of the control element circuitry. This configuration decreases the sensitivity of the circuitry to process parameters, as well as different voltages and temperatures, because it mainly depends on the feedback from the package inductance. If process models are slow, the bounce at the inductor L220 will be low and the circuit will be faster. Yet, if the process models are fast, the bounce at the inductor L220 will be greater, and the circuit will be slower, thus trying to neutralize the effect of process conditions on propagation delays.

It will be appreciated by those skilled in the art that the circuitry explained above is for reducing ground bounce. It will also be appreciated that similar circuitry may be used for controlling VDDBUMP, bounce at the VDD pin, and the inductance L218 in accordance with the present invention.

That which is claimed is:

1. A CMOS buffer with significantly improved ground bounce reduction, comprising:
feedback means for sensing the ground bounce voltage at the ground terminal, connected to the input of
a controlling means for dynamically adjusting the rate of rise of the ground current in a manner that reduces the sensed ground bounce voltage to a level below a threshold while maintaining speed of operation.

2. A CMOS buffer as claimed in claim 1 wherein said feedback means is an amplifier that amplifies the difference between the sensed output ground voltage and an internal reference ground voltage.

3. A CMOS buffer as claimed in claim 1 wherein said controlling means is a slew-rate controlling circuit.

4. A CMOS buffer as claimed in claim 3 wherein said slew-rate controlling circuit is a circuit that dynamically adjusts the gate voltage of the output NMOS transistor to limit the rate of rise of the current through the ground terminal.
